(19) United States
(12) Patent Application Publication
(10) Pub. No.: US 2004/0166654 A1
(43) Pub. Date: Aug. 26, 2004

(54) Panel, liquid crystal projector, image pickup device, and digital image recognition device

(75) Inventors: Takeo Matsuda, Nagano-ken (JP); Kazuhiro Hara, Suwa-shi (JP)

Correspondence Address: SUGHRUE MION, PLLC, 2100 PENNSYLVANIA AVENUE, N.W., SUITE 800, WASHINGTON, DC, 20037, US

(73) Assignee: SEIKO EPSON CORPORATION

(21) Appl. No.: 10/677,246

(22) Filed: Oct. 3, 2003

(30) Foreign Application Priority Data
Oct. 4, 2002 (JP) 2002-292374
Aug. 6, 2003 (JP) 2003-287735

(51) Int. Cl. H01L 21/301; H01L 21/46; H01L 21/78

(52) U.S. Cl. 438/460; 438/462

(57) ABSTRACT

A dicing method not affected by abrasion, a liquid crystal projector using the cover glass and a digital image recognition apparatus provided with the sold-state image sensing device which in turn is provided with the cover glass. After tapered grooves are formed, intermediate dicing grooves are formed in the tapered grooves beveling is carried out. Then, the cutting dicing grooves are formed from the opposite side so as to reach the intermediate dicing grooves, respectively. Thus, the base plate is cut by dicing totally three times. Alternatively, the intermediate dicing grooves are provided, and the tapered grooves are formed on the side of the glass plate which is opposite to the side thereof where the intermediate dicing grooves are provided, and thereafter, cutting dicing grooves are formed in the tapered grooves so as to reach the intermediate dicing grooves. Thus, the base plate is cut by dicing totally three times.

### BACKGROUND OF THE INVENTION

1. Technical Field of the Invention

The present invention can be used in processing of a cover glass or the like, to be used in a liquid crystal panel, a solid-state image sensing device or the like. Specifically, the present invention relates to a dicing method by which a base plate such as a glass plate or the like is diced, a cover glass processed by the dicing method, a liquid crystal projector having a liquid crystal panel with the cover glass, and a digital image recognition device with a sold-state image sensing device provided with the cover glass.

2. Description of the Related Art

Liquid crystal projectors are generally used for magnifying and projecting pictures from the personal computers onto the wall surfaces. A liquid crystal projector functions as follows: a light from a light source is separated into the three primaries, i.e., a red light (R), a green light (G), and a blue light (B); then, the respective lights are passed through a liquid crystal display device (liquid crystal panel, also referred to as a light valve) which displays the respective lights on the same liquid crystal picture; the respective lights passed through the light valve are synthesized and projected through a projection lens.

Anti-dust cover glasses (cover glass) are provided on the incidence side and on the emergence side of the liquid crystal display device (the light valve). If dust adheres to the outer surface of the liquid crystal display device, the anti-dust cover glass prevents the dust from being magnified and projected. That is, the dust is separated from the liquid crystal display surface, to be set out of focus, so that the adhesion of the dust can hardly be noticed. For this purpose, the anti-dust cover glass is thick, i.e., about 1.1 mm. The anti-dust glass is bonded to a glass constituting the outer surface of the liquid crystal display device. Therefore, for the anti-dust glass, the same kind of glass as the glass constituting the outer surface of the liquid crystal display device is used, and made of materials such as quartz glass, Neoceram, or the like. Moreover, for high light transmission, an anti-reflection film is provided on the outer surface of the cover glass.

Referring to a process of producing the anti-dust cover glass, an anti-reflection film is formed on a glass plate as a base by a vacuum evaporation. Then, the glass plate is cut along predetermined cutting lines by means of a dicing blade. Thus, the respective anti-dust cover glasses are produced.

According to one known dicing method, a glass plate having a tacky-adhesive tape bonded thereto is cut from the side opposite to the tacky-adhesive tape side of the glass plate by means of a dicing blade in such a manner that the dicing blade reaches the tacky-adhesive tape, and thus, the cutting is preformed by dicing only once.

However, this method of dicing only once sometimes causes problems such as chips or breaks in the cutting sections of the glass plate, so that the glass plate must be rejected. Moreover, the tacky-adhesive layer of the tacky-adhesive tape is scraped off by the cutting edge-of the blade, and the cutting dust, together with the tacky-adhesive, adheres to the cutting sections, which makes it difficult to clean the glass plate. Japanese Unexamined Patent Application Publication No. 9-141646 attempts to solve the foregoing problems by use of a dicing method described below.

The dicing method described in the publication will be described with reference to FIGS. 15-16. In these figures, the same reference characters denote the same elements. First, as shown in FIG. 15(A), one side of a glass plate 10 is bonded to a tacky-adhesive tape 21 to be fixed. Tapered grooves (V-grooves) 31 having a V-shaped cross-section are formed along predetermined cutting lines on the surface of the glass plate 10 by means of a tapered wide blade 41 having a V-shaped acute cutting-edge.

Subsequently, as shown in FIG. 15(B), the tacky-adhesive tape 21 is peeled off. A tacky-adhesive tape 22 is bonded to the side of the glass plate where the tapered grooves 31 are provided. Then, as shown in FIG. 15(C), dicing grooves are formed from the side opposite to the side of dicing blade 42 having a width smaller than each of the tapered grooves 31. The dicing blade is applied in such a manner that the cutting edge of the dicing blade 42 reaches the inside of the tapered grooves 31. Then, the glass plate 10 is cut.

It is stated in the publication that, according to this dicing method, the tapered grooves 31 is formed so that the cutting section is beveled, and moreover, the tacky-adhesive tape 22 is prevented from being scraped by the cutting edge of the dicing blade 42.

However, the dicing method proposed in the above-described publication has the following problems. In particular, as shown in FIG. 16(A), the cutting-edge of the dicing blade 42 being used is abraded so that the rectangular cutting-edge becomes rounded. This causes problems. For example, the dicing is carried out in such a manner that the cutting edge of the dicing blade 42a is arranged at the same position as when the edge is not abraded, so that the cutting edge of the blade is prevented from coming in contact with the tacky-adhesive tape 22. In this case, the cutting is completed in the state in which the abraded and rounded cutting edge of the dicing blade 42a is protruded in the tapered grooves 31. Accordingly, the cutting residues 51 remain protruded from the cutting sections. The cutting residues 51 remaining protruded from the cutting sections are not only undesirable from the standpoint of the size accuracy, but also may cause the glass plate to be chipped.

On the other hand, as shown in FIG. 16(B), to prevent the cutting residues 51 from remaining, the dicing blade 42a is applied in such a manner that the flat portions on the side-surfaces of the dicing blade 42a reach the tapered grooves 31. However, in this case, the cutting edge of the dicing blade 42a reaches the tacky-adhesive tape 22. Thus, the above-described problems are caused.

If the dicing blade is exchanged with a new one before it is abraded to the point that the above-described phenomena are caused, the above-described problems will not occur. However, the management of the shape and size of the cutting edges of the dicing blades is troublesome. Moreover, the cost of the glass plates is increased due to the frequent replacing of the dicing blades.

It should be noted that the above-described problems occur not only in the production of anti-dust cover glasses for liquid crystal display devices but also in cutting a base plate to produce separated plates, e.g., in cutting semiconductor wafers.

### SUMMARY OF THE INVENTION

To solve the above-described problems, it is an aspect of the present invention to provide: a dicing method in which the dicing is not affected by the abrasion of the cutting-edge of a dicing blade, a cover glass processed by the dicing method, a liquid crystal projector using the cover glass, a sold-state image sensing device provided with the cover glass, and a digital image recognition device provided with the sold-state image sensing device.

The dicing method of one embodiment of the present invention comprises: an intermediate dicing step of forming intermediate dicing grooves along predetermined cutting lines on one side of a base plate, the depth of the intermediate dicing grooves being less than the depth of the base plate, and forming inclined surfaces on both sides of the opening of each intermediate dicing groove; a bonding step of bonding a tacky-adhesive tape to the surface of the base plate where the intermediate dicing grooves are formed; and a split-dicing step of forming cutting dicing grooves on the side opposite to the side of the base plate where the intermediate dicing grooves are formed so as to be extended along the intermediate dicing grooves and reach the intermediate dicing grooves, whereby the base plate is split along the cutting lines.

In this case, in the intermediate dicing step, after formation of the intermediate dicing grooves, the inclined surfaces may be provided on both sides of the opening of each intermediate dicing groove by a blade, such as a tapered blade, having inclined surfaces.

Additionally, after formation of the tapered groove by the blade, such as the tapered blade, having inclined surfaces, the intermediate dicing groove is formed, thereby the inclined surfaces may be formed on the both side of the intermediate dicing groove.

According to the above-described embodiment of the invention, the inclined surfaces are formed on both sides of the opening of each intermediate dicing groove. Thus, the both sides of the opening of the intermediate dicing groove are beveled. Thereby, chipping can be effectively prevented.

Moreover, according to the foregoing embodiment of the invention, the intermediate dicing grooves are formed to a predetermined depth, and the cutting-dicing grooves are formed from the side of the base plate which is opposite to the side thereof where the intermediate dicing grooves are formed. Therefore, the dicing is completed before the blade for use in formation of the cutting-dicing grooves reaches the inclined surfaces formed on both sides of the opening of the intermediate dicing groove. Accordingly, the cutting is not completed in the state in which the blade for use in formation of the cutting-dicing grooves is protruded in the tapered groove (the part where the inclined surfaces axe formed), in contrast to the conventional method. Thus, no cutting residues are formed, even if the blade for use in formation of the cutting-dicing grooves is abraded.

Moreover, as described above, the dicing is completed before the cutting edge of the blade for use in formation of the cutting-dicing grooves reaches the inclined surfaces on the both sides of the opening of the intermediate dicing groove. Therefore, the cutting edge of the blade is prevented from coming into contact with the tacky-adhesive tape. Thus, it does not happen that cutting-dust, together with the tacky-adhesive, adheres to the cutting surface. The split base plates can be easily cleaned.

In this case, in the intermediate dicing step, preferably, the tapered grooves are formed on one side of the base plate along predetermined cutting lines so as to have inclined surfaces on both sides of each tapered groove, and thereafter, the intermediate dicing grooves are provided, whereby the inclined surfaces are provided on both sides of the opening of the intermediate dicing groove.

According to the above-described embodiment of the invention, the intermediate dicing grooves are formed after the formation of the tapered grooves. Thus, the formation-positions of the intermediate dicing grooves can be easily determined based on the tapered grooves. Moreover, the tapered grooves are formed before the formation of the intermediate dicing grooves. Accordingly, the cutting edge of the blade for use in formation of the intermediate dicing grooves is inserted in the tapered groove. Thus, the intermediate dicing grooves can be formed with the position of the cutting edge of the blade being fixed. Thus, the intermediate dicing grooves can be easily formed compared to the case in which no tapered grooves are formed.

The dicing method of an embodiment of the present invention comprises: an intermediate dicing step of forming intermediate dicing grooves along predetermined cutting lines on one side of a base plate, the depth of the intermediate dicing grooves being less than the depth of the base plate: a bonding step of bonding a tacky-adhesive tape to the surface of the base plate where the intermediate dicing grooves are formed: a tapered groove formation step of forming tapered grooves on the side of the base plate opposite to the side thereof where the intermediate dicing grooves are formed, along the intermediate dicing grooves so as to have inclined surfaces on both sides of each tapered groove; and a split-dicing step of forming cutting-dicing grooves substantially along the centers of the tapered grooves, the cutting-dicing grooves having a width smaller than the tapered grooves and reaching the intermediate dicing grooves, whereby the base plate is split along the cutting lines.

According to the above-described embodiment of the invention, the inclined surfaces are formed on both sides of the opening of each cutting-dicing groove, caused by the formation of the tapered grooves. Thus, the cutting surfaces are beveled. Thereby, chipping can be effectively prevented.

Moreover, according to an embodiment of the present invention, after the intermediate dicing grooves are formed, the tapered grooves and the cutting-dicing grooves are formed on the opposite surface. The splitting of the base plate is completed when the blade for use in formation of the cutting-dicing grooves reaches each intermediate dicing groove. Accordingly, the cutting is not completed in the state in which the blade for use in formation of the cutting-dicing grooves is protruded in the tapered groove, in contrast to the conventional method. Thus, no cutting residues are formed, even if the blade for use in formation of the cutting-dicing grooves is abraded. Thereby, chipping can be also prevented effectively.

Moreover, after the intermediate dicing grooves are formed, the tapered grooves and the cutting-dicing grooves are formed on the opposite-side surface. Thus, the dicing is completed before the cutting edge of the blade for use in formation of the cutting-dicing grooves reaches the tacky-adhesive tape bonded to the surface where the intermediate dicing grooves are formed. Therefore, it does not occur that cutting dust, together with the tacky-adhesive, adheres to the base plate. The base plate can be easily cleaned.

Moreover, after the tapered grooves are formed, the cutting-dicing grooves are formed. Thus, the formation-positions of the cutting-dicing grooves can be easily determined based on the tapered grooves. Moreover, the tapered grooves are formed before the formation of the cutting-dicing grooves. Accordingly, the cutting edge of the blade for use in formation of the cutting-dicing grooves is inserted in the tapered groove. Thus, the cutting-dicing grooves can be formed with the position of the cutting edge of the blade being fixed. Thus, the cutting-dicing grooves can be easily formed compared to the case in which no tapered grooves are formed.

In this case, according to an aspect of an embodiment of the present invention, preferably; the method further comprises a first bonding step of bonding a first tacky-adhesive tape to the opening on one side of a frame-shaped jig for fixing the base plate to the dicing apparatus, and securing the other-side surface of the base plate to the first tacky-adhesive tape. The above-described bonding step succeeding the intermediate dicing step is a second bonding step. In the second bonding step, preferably, a second tacky-adhesive tape, which is the above-described tacky-adhesive tape, is bonded so as to cover the opening on the other side of the jig, the second tacky-adhesive tape is bonded to the surface of the base plate where the intermediate dicing grooves are formed, and the first tacky-adhesive tape is released.

Previously, a method has been used in which, when a base plate is diced, the base plate is placed on a table provided with a suction mechanism of a dicing apparatus, and is suction-fixed. According to this method, the suction-mechanism must be provided on the table. Thus, problems are caused in which the structure of the dicing apparatus becomes complicated. On the other hand, according to an embodiment of the present invention, the base plate is fixed to the frame-shaped jig via the tacky-adhesive tape. Accordingly, when the base plate is diced, the frame-shaped jig may be fixed with just a clamp. Thus, it is not necessary to suction-fix the base plate for dicing. The suction-mechanism is unnecessary. The structure of the dicing apparatus can be simplified.

In an exemplary embodiment of the present invention, an example of the base plate is a glass plate. Preferably, the thickness of the glass plate is in the range of 0.5 mm to 2 mm.

Since the thickness of the glass plate is in the range of 0.5 mm to 2 mm, when the glass plate is used as the cover glass fixed to an optical device, dust or the like adhering to the cover glass can be set out of focus. That is, the cover glass does not deteriorate the optical properties of the optical device.

Moreover, according to one embodiment of the present invention, preferably, an antireflection film is provided on the side of the glass plate where the intermediate dicing grooves are formed.

Preferably, a method according to the various embodiments of the invention further comprises a detection step. That is, in the case in which the glass plate having the anti-reflection film formed thereon is diced, a light is irradiated to the glass plate having the tacky-adhesive tape bonded thereto after the bonding step succeeding the intermediate dicing step, and the positions of the intermediate dicing grooves are detected by using the light reflected from or transmitted through the glass plate.

When the tacky-adhesive tape is bonded to the anti-reflection film, the anti-reflection film loses its function, or rather becomes a reflection-increasing film. Thus, the difference between the part where the anti-reflection film exists and the part where no anti-reflection film exists become noticeable. Thus, according to an embodiment of the present invention, the anti-reflection film is provided on the glass plate. At the first dicing, the grooves are formed on the side of the glass plate where the anti-reflection film is provided. The tacky-adhesive tape is bonded to the surface of the diced glass plate where the anti-reflection film is provided. The anti-reflection film is scraped off by the grooves formed at the first dicing. Accordingly, when a light is irradiated to the glass plate, the grooves can be clearly detected by use of the reflected light or transmitted light. Therefore, the second dicing can be accurately carried out from the opposite side of the glass plate.

Moreover, since the dicing can be accurately carried out, it is not necessary to provide alignment marks which become references for positioning. Ordinarily, when alignment marks are provided, the relevant part of the glass plate can not be used as a product, On the other hand, according to the present invention, it is not necessary to form alignment marks, and thus, the yield of products can be enhanced. To put it another way, the glass plate can free of alignment marks.

The cover glass of the present invention is characterized in that the glass is processed by the above-described dicing method.

As seen in the above description, according to the embodiments of the present invention, no chipping occurs, and no cutting residues are formed, when the cover glass is processed by the above-described dicing method.

For use, the above-described cover glass can be bonded to the substrates of a liquid crystal panel in which an electro-optical material may be sealed between a pair of the substrates. Moreover, the liquid crystal panel may be mounted on a liquid crystal projector.

When the above-described cover glass is bonded to a pair of the substrates, dust, even if it adheres to the cover glass, can be set out of focus, due to the separation between the dust and a pair of the substrates. Thus, influences of dust or the like to be exerted over a projected image can be eliminated.

Moreover, the above-described cover glass may be used in a sold state image sensing device. That is, the sold-state image sensing device of the present invention comprises a casing having an opening formed thereon, a sold-state image sensing device accommodated in the casing, and the cover glass arranged in opposition to the sold-state image sensing device so as to cover the opening of the casing. Thereby, the solid-state image sensing device can be protected.

Furthermore, the sold-state image sensing device can be mounted on a digital image recognition device.

### BRIEF DESCRIPTION OF THE DRAWINGS

The above aspects and advantages of the present invention will become more apparent by describing in detail illustrative, non-limiting embodiments thereof with reference to the accompanying drawings, in which:

FIG. 1 is a perspective view of a dicing apparatus which carries out the dicing method according to a first illustrative, non-limiting embodiment of the present invention.

FIGS. 2(A) through 3(H) schematically show the respective steps of the dicing method.

FIGS. 4(A) through 4(E) show in section the respective steps of the dicing method.

FIG. 5 is a cross-sectional view of an illustrative modification of a tapered blade employed in the dicing method.

FIG. 6 graphically illustrates the difference between the reflectivities obtained when a tacky-adhesive tape bonded to the surface of an anti-reflection film and when no tacky-adhesive tape is bonded thereto.

FIG. 7 is a schematic view of a liquid crystal projector using a cover glass obtained by the dicing method.

FIG. 8 is a cross-sectional view of a liquid crystal panel of the liquid crystal projector.

FIGS. 9(A) through 9(E) are cross sectional views showing the respective steps of a dicing method according to a second, illustrative, non-limiting embodiment of the present invention.

FIGS. 10(A) through 10(E) are cross sectional views showing the respective steps of a dicing method according to a third, illustrative, non-limiting embodiment of the present invention.

FIG. 11 is a cross-sectional view of a sold-state image sensing device using a cover glass obtained by the dicing method.

FIG. 12 is a perspective view showing a digital camera on which the sold-state image sensing device is mounted.

FIG. 13 is a perspective view of a video camera on which the sold-state image sensing device is mounted.

FIGS. 14(A) and 14(B) are cross-sectional views of a dicing method of the present invention.

FIGS. 15(A) through 15(C) are cross-sectional views of a known dicing method.

FIGS. 16(A) and 16(B) are cross-sectional views which illustrate problems of the known dicing method.

### DETAILED DESCRIPTION OF THE INVENTION

The present invention will now be described in detail by describing illustrative, non-limiting embodiments thereof with reference to the accompanying drawings. In the drawings, the same reference characters denote the same elements. The present invention is not restricted to the below-described embodiments.

### 1. First Embodiment

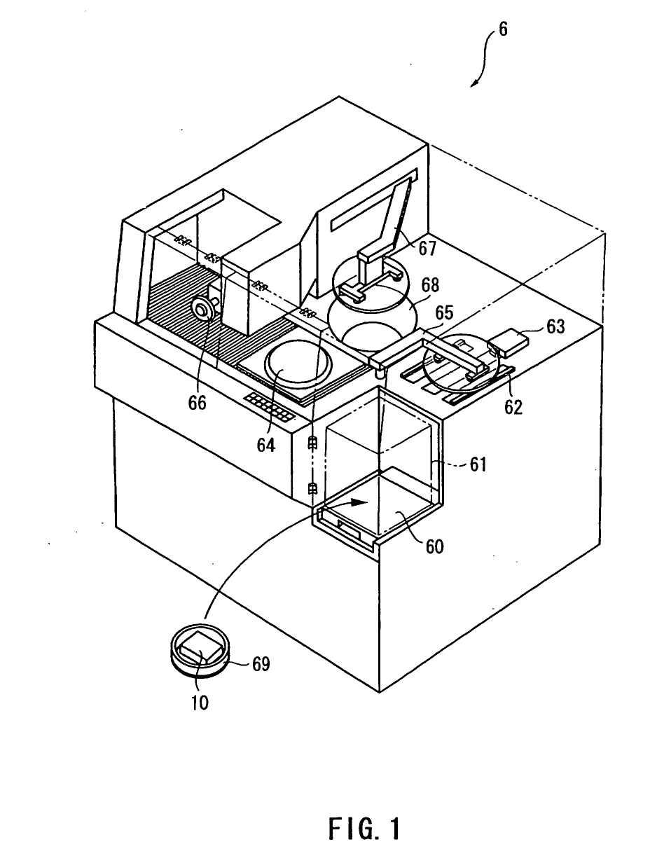

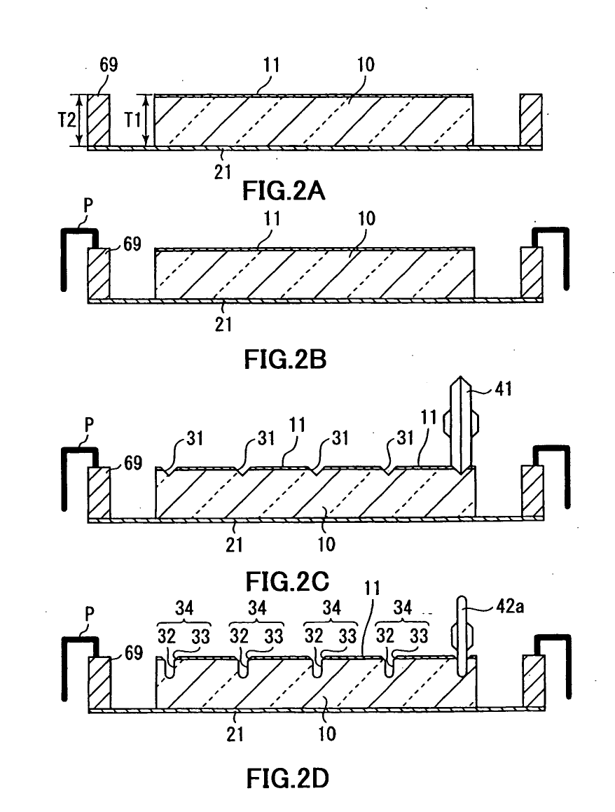

FIG. 1 shows a dicing apparatus 6 which dices a glass plate 10 as a base plate. The glass plate 10 is made of a material having a small coefficient of thermal expansion such as quartz glass, borosilicate glass, or the like. However, these materials are not restrictive. The glass plate 10 may be formed of an ordinary material such as soda line glass, non-alkali glass or the like. As shown in FIG. 2, the thickness T1 of the glass plate 10 is in the range of 0.5 mm to 2.0 mm. An anti-reflection film 11 is provided on one side of the glass plate 10. The anti-reflection film 11 is composed of a single or multi-layer of organic films or inorganic films. However, the constitution of the anti-reflection film 11 has no particular limits.

The dicing apparatus 6 comprises a cassette 61 for accommodating the glass plate 10, a cassette stand 60 on which the cassette 61 is placed and which can be vertically moved, a transfer mechanism 63 for transferring the glass plate 10 from the cassette 61 to a temporary placement portion 62, a first conveying mechanism 65 for conveying the glass plate 10, placed on the temporary placement portion 62, from the temporary placement portion 62 to a chuck table 64, a dicing mechanism 66 for dicing the glass plate 10 placed on the chuck table 64, and a second conveying mechanism 67 for conveying the diced glass plate 10 to a cleaning means 68.

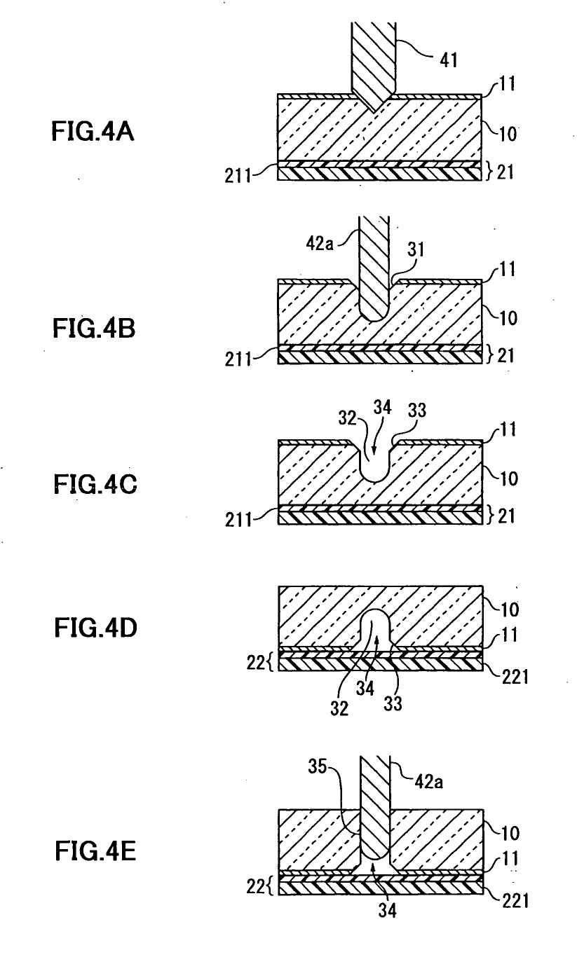

The dicing mechanism 66 has two types of blades, i.e., a tapered blade 41 (see FIGS. 2 and 4) whose cutting edge is tapered, and a dicing blade 42a (see FIGS. 2 and 4) whose cutting edge is straight.

In addition, to detect the dicing positions of the glass plate 10 placed on the chuck table 64, an irradiating means (not shown) for irradiating a light onto the glass plate 10 placed on the chuck table 64 and an image pickup means (not shown) for picking up the reflected light or transmitted light such as a CCD (charge coupled device) camera or the like are installed in the vicinity to the dicing mechanism 66.

The glass plate 10 is diced using the dicing apparatus 6 as follows. This will be described with reference to FIGS. 1 through 4. First, as shown in FIG. 2(A), the glass plate 10 is fixed to a jig 69. The jig 69 is used to connect the glass plate 10 to the chuck table 64 of the dicing apparatus 6. The jig 69 is a frame member having a substantially plane-ring shape. For the jig 69, the parts thereof corresponding to the front and back sides of the glass plate 10 are of the thickness T1 of the glass plate 10 and the thickness of the anti-reflection film 11.

A first tacky-adhesive tape 21 is bonded to one of the open portions of the jig 69. Then, the side of the glass plate 10 opposite to the side thereof where the anti-reflection film 11 is provided is bonded and fixed to the first tacky-adhesive tape 21 via the tacky-adhesive layer 211 of the tape 21 (see FIG. 4) (first bonding process).

In this case, preferably, the first tacky-adhesive tape 21 has such properties that the tacky-adhesive layer 211 ordinarily has a high tacky-adhesion strength, and can be cured by irradiation of ultraviolet rays, electron beams, or the like so that the tacky-adhesion strength is significantly reduced, and the layer can be readily released.

Subsequently, the glass plate 10 fixed to the jig 69 is accommodated in the cassette 61 of the dicing apparatus 6. The glass plate 10 fixed to the jig 69 is transferred from the cassette 61 by means of the transfer mechanism 63, and is placed on the temporary placement portion 62. Moreover, the jig 69 and the glass plate 10 placed on the temporary placement portion 62 are transferred to the chuck table 64 by means of the first conveying mechanism 65.

Then, as shown in FIG. 2(B), the jig 69 is fixed to the chuck table 64 by means of a fixing clamp P. Thus, the glass plate 10 is fixed to the chuck table 64. The fixing clamp P is attached to the end-face on the other opening side of the jig 69.

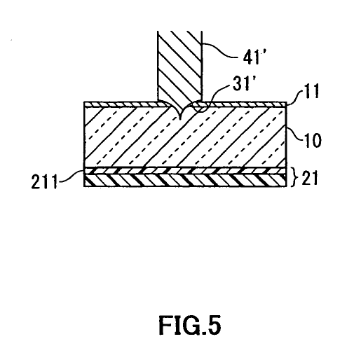

Then, as shown in FIG. 2(C) and FIG. 4(A), tapered grooves 31 each having inclined surfaces on both sides thereof and a V-shaped cross-section are formed along predetermined cutting lines on the side of the glass plate 10 where the anti-reflection film 11 is provided, by means of a tapered blade 41 having a tapered cutting edge and, a V-shaped cross-section. Regarding the size of the tapered blade 41, the extending angle at the cutting edge of about 90° is preferable. However, this is not restrictive. For example, a blade 41′ whose cutting edge is concaved inwardly into an arch shape in order to form a taper as shown in FIG. 5, may be used to form tapered grooves 31′ having round bevels. Thus, the shape of the tapered grooves has no particular limitations.

Subsequently, an intermediate-dicing step is carried out as shown in FIG. 2(D) and FIG. 4(B), in which the intermediate-dicing grooves 32 are formed substantially along the center lines of the tapered grooves 31 by means of the dicing blade 42a whose width is smaller than each of the tapered grooves 31. The depth of the intermediate dicing grooves 32 is less than the thickness of the glass plate 10 so that the glass plate 10 is not cut off. The dicing blade 42a used in this case may have a round cutting edge caused by abrasion, as shown in FIG. 2(D) and FIG. 4(B).

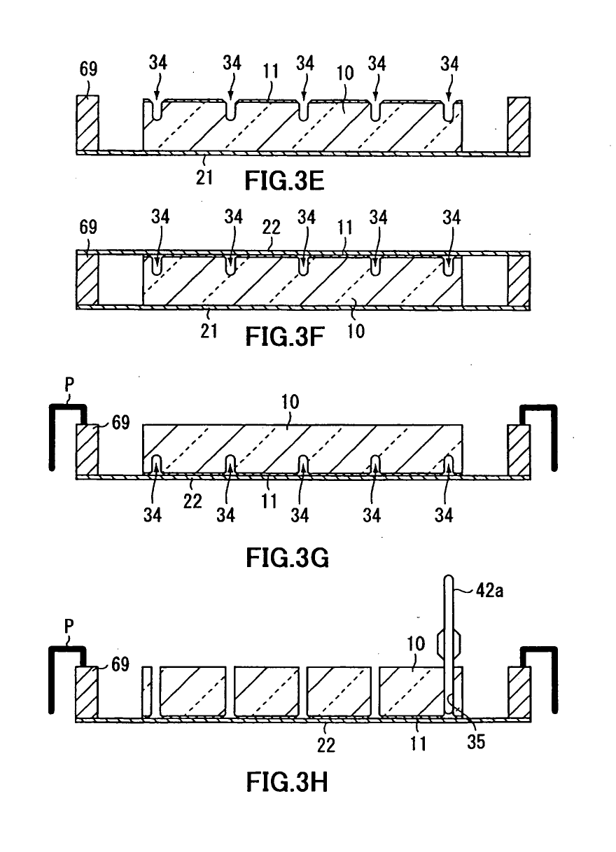

As shown in FIG. 2(D), FIG. 3(E), and FIG. 4(C), the glass plate 10 subjected to the intermediate dicing step obtains beveled intermediate dicing grooves 34 on the side of glass plate 10 where the anti-reflection film 11 is provided. The bevels 33 are formed in the openings of the intermediate dicing grooves 32 provided along the grooves 31 formed by means of the tapered blade 41 and obliquely inclined on both sides of the center line.

Subsequently, as shown in FIG. 3(F), the fixing clamp P is removed from the jig 69. Ultraviolet rays or the like are irradiated to the first tacky-adhesive tape 21, so that the tacky-adhesive layer 211 is cured, resulting in the reduction of the tacky-adhesion strength. A second tacky-adhesive tape 22 having the same properties as the first tacky-adhesive tape 21 is arranged so as to cover the other opening of the jig 69, and is bonded to the anti-reflection film 11 via the tacky-adhesive layer 221 (see FIG. 4(D)). Thereafter, the first tacky-adhesive tape 21 is released. Thus, the second bonding step is carried out.

Subsequently, as shown in FIG. 3(G), an operator turns the jig 69 upside down by the operator's hand, so that the glass plate 10 is inverted, i.e., the side of the glass plate 10 where no beveling intermediate dicing grooves 34 are formed is positioned to be on the upper side. Then, the fixing clamp P is fixed to the jig 69 again, and the jig 69 is secured to the chuck table 64.

Next, a detecting step is carried out, in which the positions of the beveling intermediate dicing grooves 34 are detected. FIG. 3(G) and FIG. 4(D) show the glass plate 10 for which the detecting step is carried out. As shown in FIG. 3(G) and FIG. 4(D), the beveling intermediate dicing grooves 34 each having at least one of the bevels 33 are provided on the glass plate 10. The anti-reflection film 11 is removed from the parts of the glass plate 10 where the grooves 34 are formed. The second tacky-adhesive tape 22 is bonded to the anti-reflection film 11.

The anti-reflection film 11 is so designed that the reflection at the interface between the air and the glass plate 10 is suppressed, so that the light transmission is enhanced. The anti-reflection film 11 is effective in suppressing a light from being reflected toward the air side when the light is incident on the glass plate 10 from the air side, and also in suppressing a light from being reflected toward the glass plate 10 side, when a light transmitted through the glass plate 10 is emerged toward the air side. However, in the case in which the tacky-adhesive layer 221 of the second tacky-adhesive tape 22 is closely bonded to the surface of the anti-reflection film 11, the anti-reflection film 11 loses its function as an anti-reflection film, since the tacky-adhesive layer 221 has a higher refractive index than the air, or rather the reflection is enhanced compared to the case in which no anti-reflection film is provided. Thus, the anti-reflection film 11 functions as a reflection-increasing film.

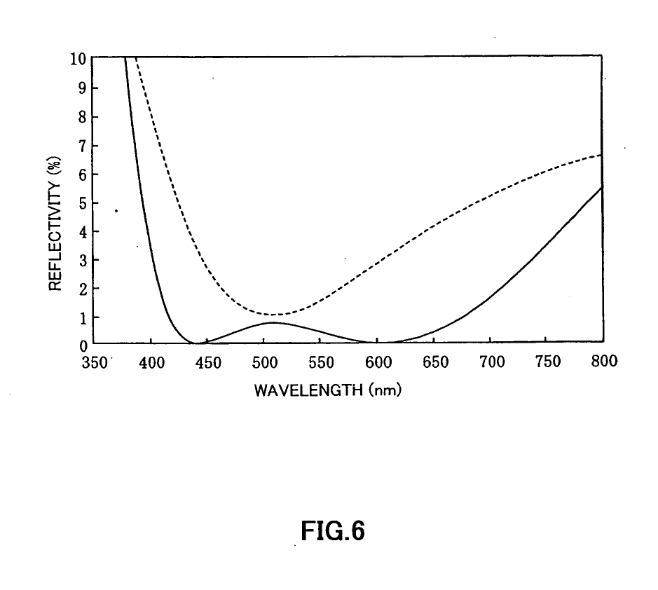

FIG. 6 is a graph showing the spectroscopic spectra of the reflectivity of an anti-reflection film composed of multi-layers, i.e., four layers. The solid line represents the reflectivity (%) of the glass plate when it has no tacky-adhesive tape bonded thereto and thus, has an interface to the air. The broken line represents the reflectivity of the glass plate when it has a tacky-adhesive tape bonded thereto. The bonding of the tacky-adhesive tape remarkably increases the reflectivity. The average value of the spectral reflectivity in the range of 400 nm to 700 nm is 0.62% for the air. The bonding of the tacky-adhesive tape causes the average value to increase to 3.17%.

To detect the beveling intermediate dicing grooves 34 formed in the glass plate 10, as shown in FIG. 3(G) and FIG. 4(D), from which the anti-reflection film 11 has been partially removed, a light is irradiated to the glass plate 10 having the second tacky-adhesive tape 22 bonded onto the anti-reflection film 11, from the uncut side of the glass plate 10 where the cutting dicing grooves are to be provided or from the second tacky-adhesive tape 22 side in the direction vertical to the glass plate 10. Then, the reflected light or transmitted light is picked up by means of an image pickup means such as a CCD camera or the like.

Referring to an image formed by picking up the reflected light, the reflected light quantity on the anti-reflection film 11 is relatively larger than that of the beveling intermediate dicing groove 34. The part of an image corresponding to the beveling intermediate dicing grooves 34 is dark. Thus, the beveling intermediate dicing grooves 34 can be detected as the dark portions of the image. Moreover, regarding an image formed by picking up the transmitted light, the reflection is relatively strong on the part of the glass plate 10 where the anti-reflection film 11 exists, and thus, the transmitted light quantity is small. The reflected light quantity is small, and the transmitted light quantity is large in the beveling intermediate dicing grooves 34. Thus, the beveling intermediate dicing grooves 34 are relatively light compared to their surroundings. Accordingly, the beveling intermediate dicing grooves 34 can be detected as the light portions of the image. For example, the above-described CCD image is binary-coded, and thus, the positions of the beveling intermediate dicing grooves 34 and those of the intermediate dicing grooves 32 can be processed by a computer.

Then, as shown in FIG. 3(H) and FIG. 4(E), cutting dicing grooves 35 are formed on the sections of the opposite side of the glass plate 10 substantially corresponding to the centers of the beveling intermediate dicing grooves 34 whose positions have been detected, so as to accurately overlap the intermediate dicing grooves 32 by means of the dicing blade 42a. Thus, the intermediate dicing grooves 32 are caused to communicate with the cutting dicing grooves 35, respectively. Thus, a splitting-dicing step in which the glass plate 10 is split is carried out. In this case, the splitting-dicing step is completed when the cutting edge of the dicing blade 42a reaches a position, e.g., about 0.1 mm distant from the second tacky-adhesive tape 22.

Thereafter, UV rays or the like are irradiated to the second tacky-adhesive tape 22, so that the tacky-adhesive layer 221 is cured, resulting in the reduction of the tacky-adhesion force of the tacky-adhesive layer 221. Then, the split glass plates are released from the second tacky-adhesive tape 22, respectively. Thereafter, the split glass plates are conveyed to the cleaning means 68 for cleaning by means of the second conveying means 67. Moreover, the split glass plates are transferred to the temporary placement portion 62 by means of the first conveying means 65, and are accommodated at predetermined positions in the cassette 61 by means of the transferring mechanism 63.

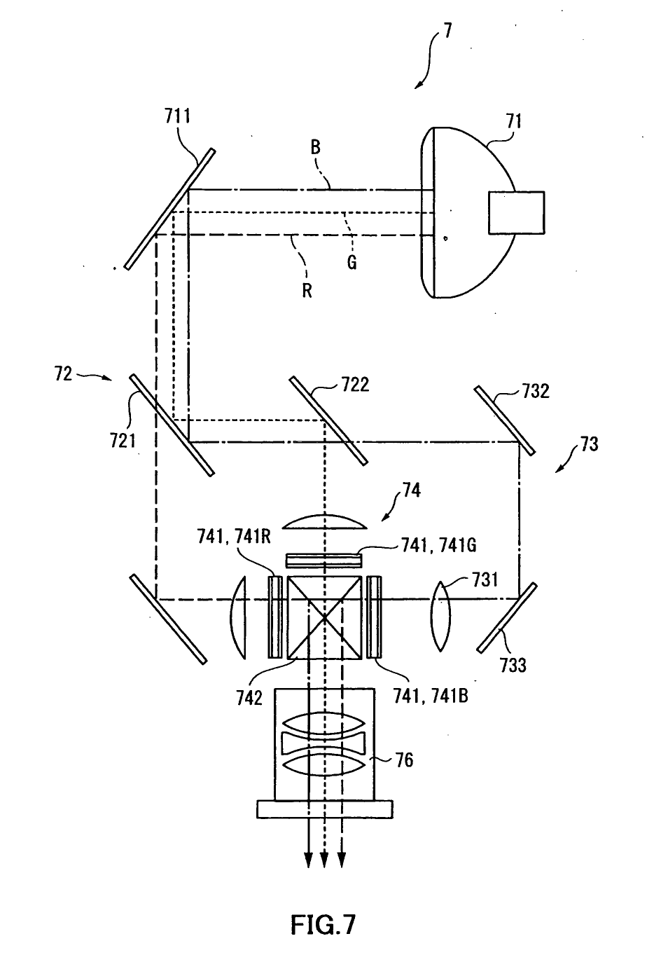

Each split glass plate formed by dicing the glass plate 10 as described above is used as cover glasses 1, and, e.g., is mounted on a liquid crystal projector 7 shown in FIG. 7. The liquid crystal projector 7 modulates a luminous flux emerged from a light source corresponding to an image information, and magnifies and projects the luminous flux onto a projection plane such as a screen or the like. The liquid crystal projector 7 comprises a light source 71, a homogeneously illuminating optical system (not shown), a color-separation optical system 72; a relay optical system 73, an optical device 74 containing a cross-dichroic prism 742 as a color synthesizing system, and a projection lens 76 as a projection optical system.

The homogeneously illuminating optical system divides a luminous flux emerged from the light source 71 into a plurality of partial luminous fluxes. The respective partial luminous fluxes are superposed in an image-forming area of a liquid crystal panel 741 (described below) of the optical device 74.

A luminous flux emerged from the light source 71 is reflected by a reflection mirror 711, and is caused to enter the color-separation optical system 72. The color-separation optical system 72 comprises a dichroic mirror 721 which reflects a blue light (B) and a green light (G), and transmits a red light (R), and a dichroic mirror 722 which transmits the blue light (B) and reflects the green light (G). Thus, the color-separation optical system 72 separates the luminous flux emerged from the illuminating optical system into the red light (R), the green light (G), and the blue light (B).

The relay optical system 73 guides the blue light (B), transmitted through the dichroic mirror 722, to the cross-dichroic prism 742, and is provided with a relay lens 731 and reflection mirrors 732 and 733.

The optical device 74 modulates the luminous flux which has entered there, and corresponds to the image information, to form a color image, and is provided with liquid crystal panels 741 (741R, 741G, and 741B) and the above-mentioned cross-dichroic prism 742.

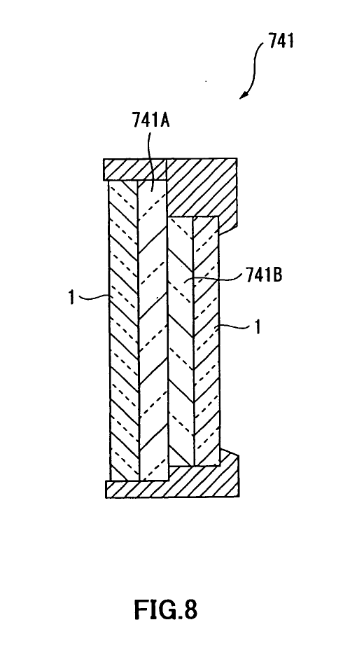

A liquid crystal panel 741, as shown in FIG. 8, comprises a driving substrate 741A (e.g., a substrate in which a plurality of line electrodes, electrodes constituting pixels, and TFT elements electrically connected between them are formed), an opposed substrate 741B (e.g., a substrate having commonly-used electrodes), and a liquid crystal (electro-optical substance) which is sealed between them. A control cable (not shown) is provided so as to extend from a position between the substrates 741A and 741B. The cover glasses 1 split by the above-described dicing method are secured to the substrates 741A and 741B.

Thereby, the positions of the panel planes of the liquid crystal panels 741 are shifted from the back-focusing positions of the surface can not be recognized significantly optically.

According to the above-described first embodiment, the following advantages can be obtained.

1. The intermediate dicing grooves 32 are formed after the tapered grooves 31 each having a V-shaped cross-section are formed. Accordingly, inclined surfaces are provided on both sides of the opening of each intermediate dicing groove 32. Thus, the bevels 33 are formed on the cutting surfaces on both sides of the opening of the intermediate dicing groove 32. Thereby, the chipping can be effectively prevented. Regarding the split glass plates (cover glass 1), the generation of the rejected products can be suppressed, and the amount of production can be increased.

2. The beveling intermediate dicing grooves 34 each having a predetermined depth are formed, and the cutting dicing grooves 35 are formed from the side of the glass plate 10 which is opposite to the side thereof where the beveling intermediate dicing grooves 34 are formed.

Thus, the dicing is completed before the dicing blade 42a for use in formation of the cutting dicing grooves 35, reaches the inclined surfaces formed on the both sides of the opening of each beveling intermediate dicing groove 34.

Accordingly, the cutting is not completed in the state in which the dicing blade 42a, for use in formation of the cutting dicing grooves 35, is protruded in each tapered groove (the parts of the groove where the inclined surfaces are formed) in contrast to the conventional dicing. Therefore, even if the dicing blade 42a for use in formation of the cutting dicing grooves 35 is abraded, cutting residues are not formed in contrast to the conventional dicing. Thus, regarding the split glass plates, i.e., the cover glasses 1, the generation of the rejected products can be suppressed, and the amount of production can be increased.

Moreover, the dicing blade 42a, even if it is abraded, can be used. Thus, the service life of the dicing blade 42a is longer. Also, the cutting edge of the dicing blade 42a can be simply managed with respect to the abrasion. The cost can be reduced.

3. In addition, as described above, the dicing is completed before the cutting edge of the dicing blade 42a for use in formation of the cutting dicing grooves 35 reaches the inclined surfaces formed on the both sides of the opening of the respective beveling intermediate dicing grooves 34. Therefore, the cutting-edge of the dicing blade 42a is prevented from contacting the second tacky-adhesive tape 22. Accordingly, cutting dust, together with the tacky-adhesive, is prevented from adhering to the split glass plates. Thus, the cleaning of the split glass plates can be easily performed.

4. In this embodiment, the intermediate dicing grooves 32 are formed after the formation of the tapered grooves 31. Accordingly, the formation-positions of the intermediate dicing grooves 32 can be easily determined based on the tapered grooves 31, respectively. Moreover, since the tapered grooves 31 have been already formed, the cutting edge of the dicing blade 42a for forming the intermediate dicing groove 32 can be inserted into each of the tapered grooves 31, and with the cutting-edge of the dicing blade 42a being fixed, the intermediate dicing grooves 32 can be formed. Accordingly, the intermediate dicing grooves 32 can be formed more easily compared to the case in which no tapered groves exist.

5. There is a method in which when a glass plate is diced, the glass plate is placed on a table provided with a suction-mechanism, and is fixed by a suction. In this embodiment, the glass plate 10 is fixed to the jig 69 via the tacky-adhesive tapes 21 and 22. Accordingly, when the glass plate 10 is diced, the jig 69 is fixed to the chuck table 64. Thus, for the dicing, fixing of the glass plate 10 by the suction-is not necessary. Thus, the suction mechanism is not needed. The structure of the dicing apparatus 6 can be simplified.

6. Moreover, in this embodiment, the glass plate 10 is attached to the jig 69. Accordingly, when the glass plate 10 is inverted to form the cutting dicing grooves 35, the inversion can be performed by holding the jig 69. It is not necessary to directly hold the glass plate 10. Thus, the breaking or the like of the glass plate 10 can be prevented.

7. The thickness of the glass plate 10 is set to be between 0.5 mm and 2 mm. Accordingly, when the split glass plate is used as the cover glass 1 fixed to the liquid crystal panel 741, dust or the like adhering to the cover glass 1 can be set out of focus. That is, the cover glass 1 does not deteriorate the optical properties of the liquid crystal panel 741.

8. In this embodiment, the tacky-adhesive tape 22 is bonded to the anti-reflection film 11. Therefore, the anti-reflection film 11 loses the function of preventing reflection, and becomes a reflection-increasing film. The part of the image corresponding to the presence of the anti-reflection film 11 is distinctly different from the part of the image corresponding to the absence of the anti-reflection film 11. The anti-reflection film 11 is scraped off by the beveling intermediate dicing grooves 34 provided at the first dicing. The beveling intermediate dicing grooves 34 can be clearly detected by irradiating a light to the glass plate 10 and utilizing the reflected light or the transmitted light. The second dicing can be accurately carried out from the opposed side of the plate 10.

As described above, the dicing can be accurately carried out. Accordingly, it is not necessary to form alignment marks for accurate positioning on the glass plate 10. Ordinarily, in the case in which an alignment mark is formed, the relevant part can not be used as a product. According to this embodiment, it is not necessary to form an alignment mark, i.e., generating the useless part in which an alignment mark is formed. The whole glass plate 10 as a base can be split to produce products. As a result, the yield is high, and the production cost can be reduced.

### 2. Second Embodiment

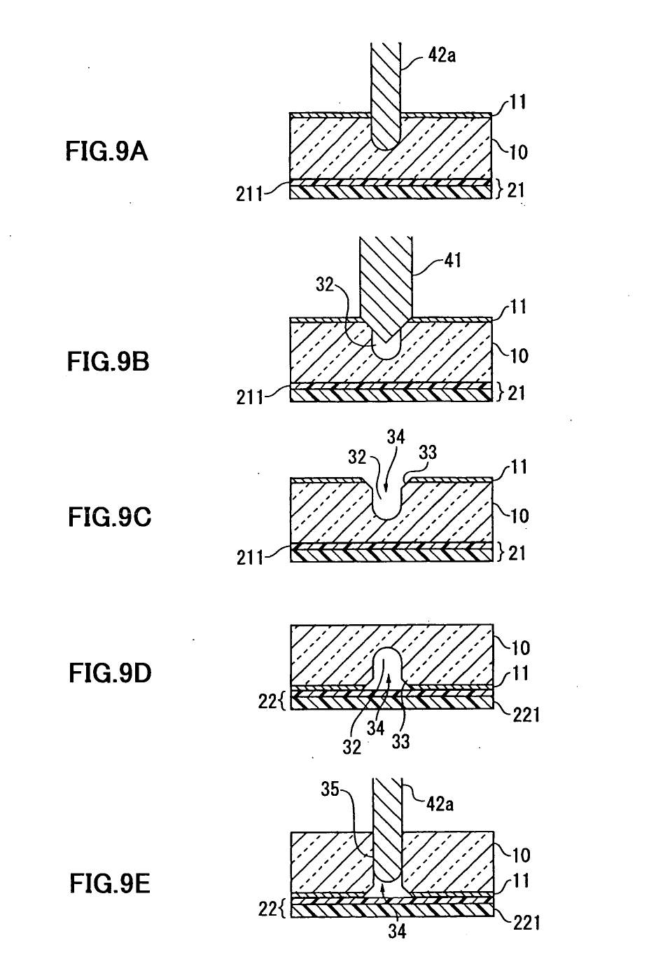

Hereinafter, a dicing method according to a second embodiment of the present invention will be described with reference to FIG. 9. In the description made below, the same parts as described previously are designated by the same reference numerals, and the description is not repeated.

According to the first embodiment, in the intermediate dicing process, the tapered grooves 31 are formed, and then, the intermediate dicing grooves 32 are formed. Thereby, the beveling of the openings of the intermediate dicing grooves 32 is carried out. According to the second embodiment, first, the intermediate dicing grooves 32 are formed, and then, the opening portions of the intermediate dicing grooves 32 are beveled. The second embodiment is the same as the first embodiment in other respects.

According to the second embodiment, first, as shown in FIG. 9(A), the intermediate dicing grooves 32 are formed along predetermined cutting lines on the surface of the glass plate 10 where the anti-reflection film 11 is provided by means of the dicing blade 42a, as shown in FIG. 9(A). The depth of the respective intermediate dicing grooves 32 is set to be less than the thickness of the glass plate 10 to prevent the glass plate 10 from being cut off. Regarding the dicing blade 42a used here, the cutting-edge may be abraded to be rounded as shown in FIG. 9.

Subsequently, as shown in FIG. 9(B), bevels 33 are formed so as to be inclined on both sides of the opening of the respective intermediate dicing grooves 32 by means of the tapered blade 41, having V-shaped cross-section, whose cutting edge is a tapered edge substantially with respect to the center of the intermediate dicing groove 32.

According to the above-described dicing method of the second embodiment, the beveling intermediate dicing grooves 34 are formed on one side of the glass plate 10, in which the bevels 33 inclined on the both sides of the opening of the respective intermediate dicing grooves 32 are formed, similarly to the dicing method of the first embodiment, as shown in FIG. 9 (C). The succeeding process is the same as that of the first embodiment as shown in FIG. 9(D) and FIG. 9(E). The description is not repeated.

According to the above-described embodiment, the same second, third, fifth and eighth advantage of the first embodiment, described above, can be obtained. In addition, the following advantages can be obtained.

1. After the intermediate dicing grooves 32 are formed, the bevels 33 are formed by means of the tapered blade 41. Thereby, the chipping can be effectively prevented. Accordingly, regarding the split glass plates, generation of rejected products can be suppressed, and the yield can be enhanced.

2. In the case in which the intermediate dicing grooves are formed after the formation of the tapered grooves, the formation of the tapered grooves will be difficult, if the cutting edge of the tapered blade for use in formation of the tapered grooves is abraded. On the other hand, according to this embodiment, the beveling is carried out by means of the tapered blade 41 after the intermediate dicing grooves 32 are formed. In other words, new grooves are not formed on the glass plate 10 by means of the tapered blade 41. Even if the tip of the cutting edge of the tapered blade 41 is abraded, no problems will be caused. Accordingly, it is not necessary to frequently maintain the cutting edge of the tapered blade 41 in addition to the blade 42a in this embodiment.

### 3. Third Embodiment

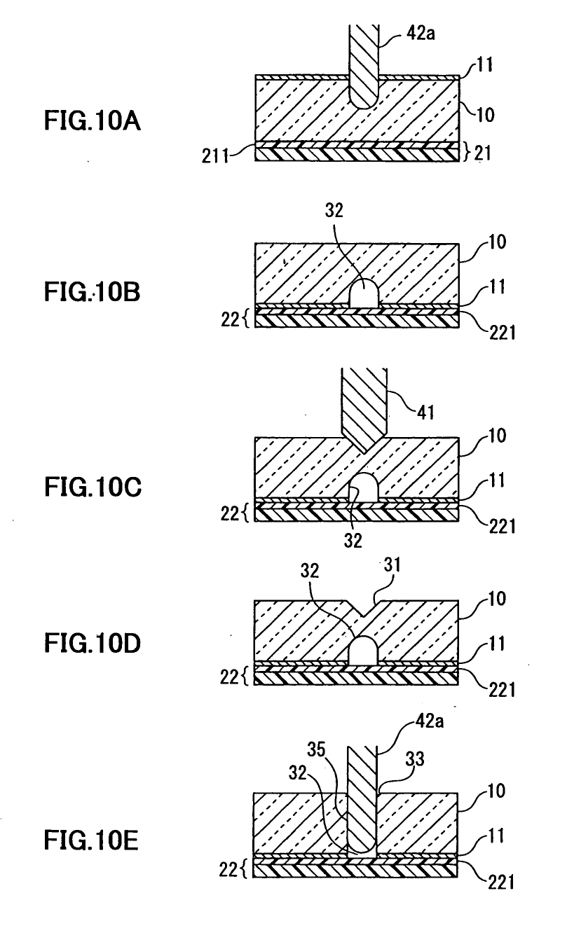

Subsequently, a dicing method according to a third embodiment will be described with reference to FIG. 10.

Also, in the third embodiment, the case in which a cover glass is produced as an example will be described. First, as shown in FIG. 10(A), a first bonding step is carried out, in which the side of the glass plate 10 which is opposite to the side thereof where the anti-reflection film 11 is provided is bonded to the first tacky-adhesive tape 21 via the tacky-adhesive layer 211.

Although not shown here, the first tacky-adhesive tape 21 is bonded to the frame-shaped jig so as to cover the opening thereof, as well as that in the first embodiment. Accordingly, the glass plate 10 is bonded to the first tacky-adhesive tape 21, and thereby, the glass plate 10 is fixed to the jig.

Subsequently, similarly to the above-described embodiment, the jig is fixed to the chuck table by means of a fixing clamp.

Then, an intermediate dicing step is carried out, in which the intermediate dicing grooves 32 are formed, by means of the dicing blade 42a, along the predetermined cutting lines on the surface of the glass plate 10 where the anti-reflection film 11 are provided. The depth of the intermediate dicing grooves 32 is less than the thickness of the glass plate 10 so that the glass plate 10 is prevented from being cut. Regarding the dicing blade 42a used here, the cutting edge may be abraded to be rounded as shown in FIG. 10(A).

Thereafter, the fixing of the jig with the clamp is released. UV rays or the like are irradiated to the first tacky-adhesive tape 21, so that the tacky-adhesive layer 211 is cured, and the tacky-adhesion force is reduced. Then, a second bonding step is carried out, in which the second tacky-adhesive tape 22 having the same properties as the first tacky-adhesive tape 21 is bonded to the anti-reflection film 11 via the tacky-adhesive layer 221, and thereafter, the first tacky-adhesive tape 21 is released, as shown in FIG. 10(B).

Subsequently, an operator turns the jig upside down by the operator's hand, so that the side of the glass plate 10 where no intermediate dicing grooves 32 are formed is set to be on the upper side. A fixing clamp is fixed to the jig, again, and the jig is secured to the chuck table.

Then, such a detection step as described above is carried out. The anti-reflection film 11 to which the tacky-adhesive layer 221 is bonded functions as a reflection-increasing film. The parts of the glass plate 10 from which the anti-reflection film 11 is removed due to the intermediate dicing grooves 32 are detected as light portions of an image taken by the transmitted light, and are detected as dark portions of an image taken by the reflected light.

The tapered groove forming process is carried out. That is, as shown in FIG. 10(C) and FIG. 10(D), the tapered grooves 31 each having inclined surfaces on both sides thereof and a V-shaped cross-section are formed at the positions on the surface of the glass plate 10 opposite to the intermediate dicing grooves 32 of which the positions have been detected, in such a manner that the tip of the tapered blade 41 correctly overlaps the center of each intermediate dicing groove 32.

Next, a split-dicing process is carried out. That is, as shown in FIG. 10(E), the cutting dicing grooves 35 are formed substantially along the centers of the tapered grooves 31 by use of the dicing blade 42a whose width is smaller than each of the tapered grooves 31, so that the intermediate dicing grooves 32 communicate to the cutting dicing grooves 35, respectively. Thus, the split-dicing process is carried out in which the glass plate 10 is split.

Thereafter, UV rays or the like are irradiated to the second tacky-adhesive tape 22, so that the tacky-adhesive layer 221 is cured and the tacky-adhesion force of the tacky-adhesive layer 221 is reduced. Then, the split glass plates are released from the tacky-adhesive tape 22, respectively. The succeeding process is the same as that in the first embodiment.

According to the above-described embodiment, the same fifth and eighth advantage of the first embodiment can be obtained. In addition, the following advantages can be obtained.

1. The cutting dicing grooves 36 are formed after the tapered grooves 31 are formed. The bevels 33 are formed on both sides of the opening of each cutting dicing groove 35. Thereby, the chipping can be effectively prevented.

2. After the intermediate dicing grooves 32 each having a predetermined depth are formed, the cutting dicing grooves 35 are formed from the side of the glass plate 10 which is opposite to the side thereof where the intermediate dicing grooves 32 are formed. Therefore, the cutting edge of the dicing blade 42a is prevented from coming into contact with the second tacky-adhesive tape 22. Thus, the cutting dust does not adhere to the split glass plate together with the tacky-adhesive, and the split glass plates can be easily cleaned.

3. The cutting dicing grooves 35 are formed after the formation of the tapered grooves 31. Thus, the formation-positions of the cutting dicing grooves 35 can be easily determined based on the tapered grooves 31. Moreover, the cutting dicing grooves 35 are formed after the formation of the tapered grooves 31. Thus, the cutting dicing grooves 35 can be formed while the position of the cutting edge of the dicing blade 42a for use in formation of the cutting dicing grooves 35 is fixed. Thereby, the cutting dicing grooves 35 can be formed more easily compared to the case in which no tapered grooves 31 exist.

4. After the intermediate dicing grooves 32 are provided, the tapered grooves 31 and the cutting dicing grooves 35 are formed on the opposite side of the glass plate 10. The splitting of the glass plate 10 is completed when the cutting dicing grooves 35 reach the intermediate dicing grooves 32, respectively. Accordingly, the cutting is prevented from being completed in the state in which the blade for use in the formation of the cutting dicing grooves is protruded in a tapered groove. Thus, even if the blade for use in the cutting dicing grooves 35 is abraded, no cutting-residues are formed.

The above and other features of the invention including various and novel method steps has been particularly described with reference to the accompanying drawings and pointed out in the claims. It will be understood that the particular methods embodying the invention are shown by way of illustration only and not as a limitation of the invention. The principles and features of this invention may be employed in varied and numerous embodiments without departing from the scope of the invention.

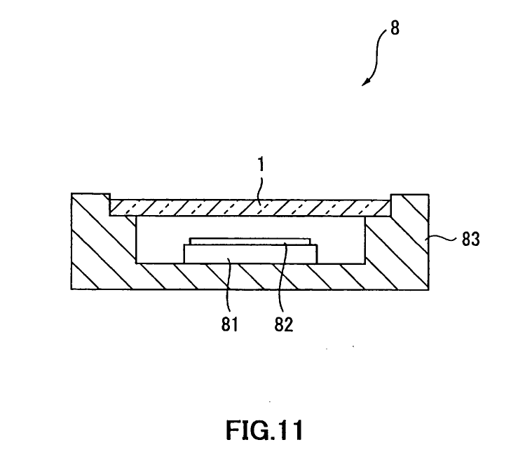

In the above-described embodiments, the cover glass 1, formed by splitting the glass plate 10, is secured to the liquid crystal panel 741 of the liquid crystal projector 7. This is not restrictive. The cover glass 1 may be used in a solid image pickup device 8 as shown in FIG. 11. The sold-state image sensing device 8 comprises a sold-state image sensing device 81 such as CCD (charge coupled device), MOS (metal-oxide semiconductor) or the like, a color filter 82 disposed on the sold-state image sensing device 81, a package (casing) 83 accommodating the sold state image sensing device 81 and the color filter 82. The cover glass 1 is attached to the opening potion of the package 83 so as to be opposed to the sold-state image sensing device 81.

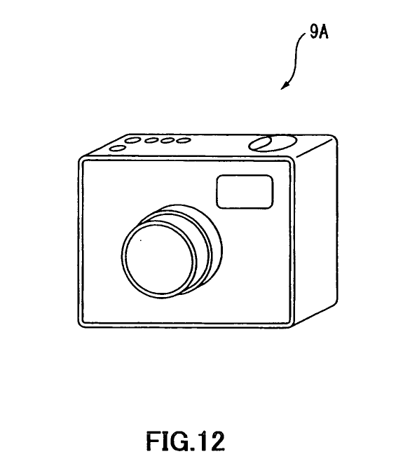

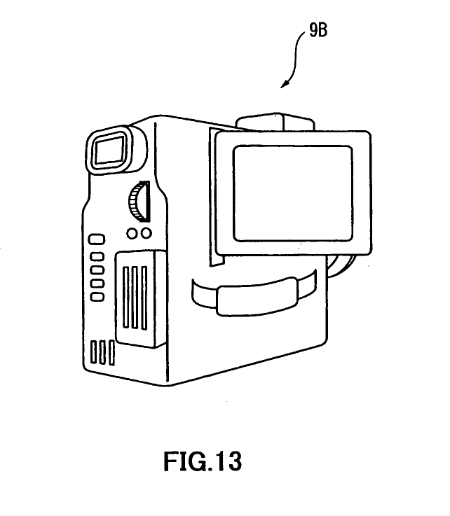

The above-described sold-state image sensing device 8 is mounted on a digital image recognition apparatus such as a digital camera 9A, a video 9B, or the like as shown in FIG. 12 and FIG. 13. In the digital camera 9A or video 9B, a subject is image-formed on the sold-state image sensing device t 81 via the color filter 82 of the sold-state image sensing device 8. The optical image is photo-electrically converted by means of the sold-state image sensing device 81. Thus, the image-data can be obtained.

In the above-described embodiments, the split glass plate is used as the cover glass 1. This is not restrictive. The split glass plates may be used as the substrates of liquid crystal display devices provided with oriented films, transparent electrodes, color filters, and so forth and as the substrates of the front plates or the like of CRTs and liquid crystal display devices.

Moreover, in the above-described embodiments, the thickness of the glass plate is set to be in the range of 0.5 mm to 2 mm. The range is not restrictive. The thickness may be appropriately set depending on the uses of the glass plate.

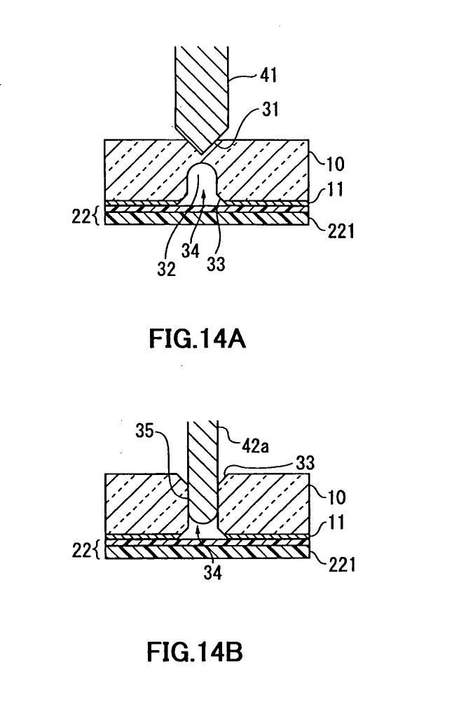

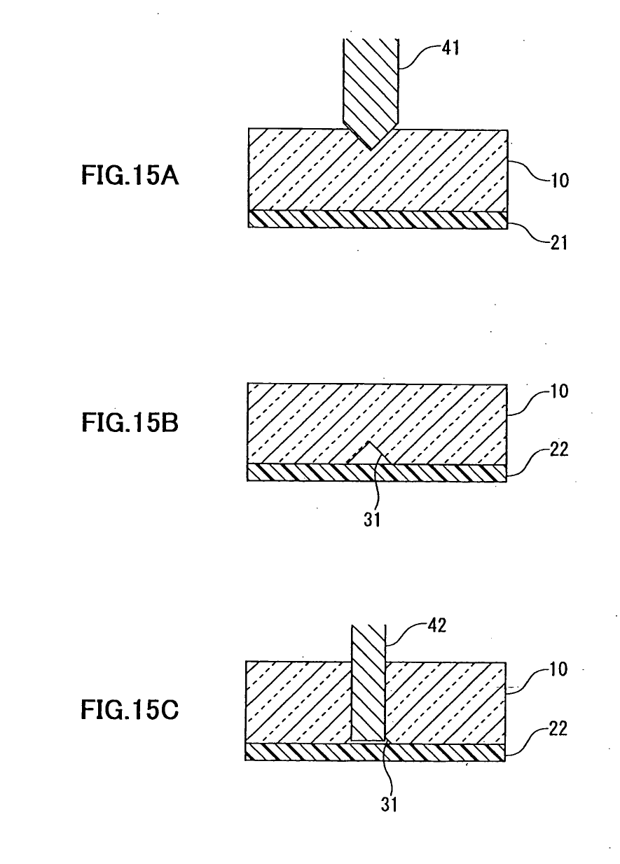

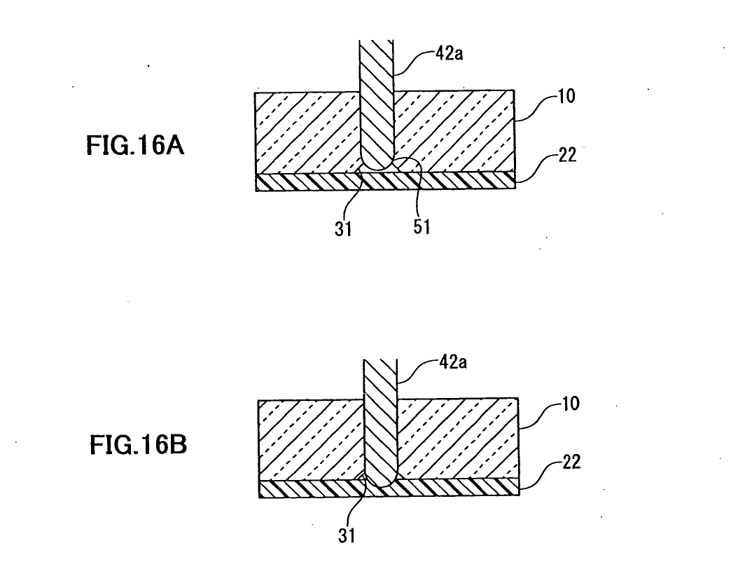

Moreover, in the above-described first to third embodiments, beveling is carried out on one side of the base plate (glass plate 10). However, for example, as shown in FIG. 14(A) and FIG. 14(B), tapered surfaces can be formed on the cutting surfaces on both sides of the base plate (glass plate 10) by additionally carrying out the tapered groove formation process in which the tapered grooves 31 are formed by means of the tapered blade 41. Thereby, the split glass plate having the beveled cutting surfaces on both sides of the plate can be provided. The chipping can be more effectively prevented.

Moreover, in the above-described embodiments, the anti-reflection film is provided on one side only of the glass plate 10. This is not restrictive. The anti-reflection films may be provided on both sides the glass plate.

The method of optically detecting the intermediate dicing grooves 32 or the beveling intermediate dicing grooves 34 are not affected by the anti-reflection films formed on both sides of the glass plate.

Moreover, the anti-reflection film needs not be provided depending on the uses of the glass plate. In addition, in the case in which a base plate provided with an alignment mark for positioning is diced, the base plate must not be transparent, i.e., the base plate needs not be a glass plate. For example, the dicing method of the present invention may be applied to semiconductor wafers on which semiconductor circuits are integrated.

Furthermore, in the above-described embodiments, the glass plate 10 is diced while the glass plate 10 is fixed to the jig 69. The dicing of the glass plate 10 may be carried out not using the jig. 69. For example, a suctioning mechanism may be provided on the chuck table. Thus, the glass plate 10 may be sucked to be fixed, and then diced. These suggested variations are not meant to be all inclusive, but merely exemplary of the kinds of variations that are permitted within the scope of the invention, the true breadth of which is defined in the claims.

What is claimed is:

1. A dicing method, comprising:
an intermediate dicing step of forming intermediate dicing grooves along predetermined cutting lines on one side of a base plate, the depth of the intermediate dicing grooves being less than the depth of the base plate, and forming inclined surfaces on both sides of the opening of each intermediate dicing groove;
a bonding step of bonding a tacky-adhesive tape to the surface of the base plate where the intermediate dicing grooves are formed; and
a split-dicing step of forming cutting dicing grooves, on a side opposite to the one side of the base plate where the intermediate dicing grooves are formed, so as to be extended along the intermediate dicing grooves and so as to reach the intermediate dicing grooves, whereby the base plate may be split along the cutting lines.

2. The dicing method according to claim 1, wherein, in the intermediate dicing step, tapered grooves are formed on one side of the base plate along the predetermined cutting lines so as to have inclined surfaces on both sides of each tapered groove, and thereafter, the intermediate dicing grooves are provided.

3. The dicing method according to claim 1, further comprising:
the bonding step succeeding the intermediate dicing step, and defining a second bonding step;
before the intermediate dicing step, a first bonding step of bonding a first tacky-adhesive tape to the opening on one side of a frame-shaped jig for fixing the base plate to the dicing apparatus; and
securing the other-side surface of the base plate to the first tacky-adhesive tape; wherein the tack-adhesive tape bonded in the second bonding step is a second tacky-adhesive tape; and
wherein the second tacky-adhesive tape is bonded to the surface of the base plate where the intermediate dicing grooves are formed, and the first tacky-adhesive tape is released.

4. The dicing method according to claim 1, wherein the base plate is a glass plate.

5. The dicing method according to claim 4, wherein the thickness of the glass plate is in the range of 0.5 mm to 2 mm.

6. A dicing method according to claim 4, further comprising disposing an anti-reflection film on the one side of the glass plate.

7. The dicing method according to claim 6, further comprising:
after the bonding step, irradiating light to the glass plate, and
detecting the positions of the intermediate dicing grooves by using light reflected from or transmitted through the glass plate.

8. A cover glass processed by the dicing method defined in claim 1.

9. A liquid crystal panel in which an electro-optical material is sealed between a pair of substrates, wherein the cover glass defined in claim 8 is attached to the substrates.

10. A liquid crystal projector, wherein the liquid crystal panel defined in claim 9 is used.

11. A sold-state image sensing device comprising a casing having an opening, a sold-state image sensing device accommodated in the casing, and the cover glass defined in claim 8 arranged in opposition to the sold-state image sensing device to close the opening of the casing.

12. A digital image recognition device having the sold-state sensing device defined in claim 11.

13. A dicing method, comprising:
an intermediate dicing step of forming intermediate dicing grooves along predetermined cutting lines on one side of a base plate, depth of the intermediate dicing grooves being less than the depth of the base plate:
a bonding step of bonding a tacky-adhesive tape to a surface of the base plate where the intermediate dicing grooves are formed:
a tapered groove formation step of forming tapered grooves on the side of the base plate opposite to the side where the intermediate dicing grooves are formed, along the intermediate dicing grooves, so as to have inclined surfaces on both sides of each tapered groove; and
a split-dicing step of forming cutting-dicing grooves substantially along centers of the tapered grooves, the cutting-dicing grooves having a width smaller than the tapered grooves and reaching the intermediate dicing grooves, whereby the base plate is split along the cutting lines.

14. The dicing method according to claim 13, further comprising:
before the intermediate dicing step, a first bonding step of:
bonding a first tacky-adhesive tape to the opening on one side of a frame-shaped jig,
fixing the base plate to the dicing apparatus by securing the other-side surface of the base plate to the first tacky-adhesive tape,
the bonding step succeeding the intermediate dicing step defining a second bonding step and the tacky-adhesive tape of the second bonding step defining a second tacky-adhesive tape;
in the second bonding step, bonding the second tacky-adhesive tape so as to cover the opening on the other side of the jig and where the intermediate dicing grooves are formed; and then
releasing the first tacky-adhesive tape.

15. The dicing method according to claim 13, wherein the base plate is a glass plate.

16. The dicing method according to claim 15, wherein the thickness of the glass plate is in the range of 0.5 mm to 2 mm.

17. The dicing method according to claim 15, further comprising disposing an anti-reflection film on the one side of the glass plate.
